(19) United States
(12) Patent Application Publication
(10) Pub. No.: US 2023/0335509 A1
(43) Pub. Date: Oct. 19, 2023

(54) POWER MODULE PACKAGE WITH MAGNETIC MOLD COMPOUND

(71) Applicant: Texas Instruments Incorporated, Dallas, TX (US)

(72) Inventor: Anindya Poddar, Sunnyvale, CA (US)

(21) Appl. No.: 17/721,271

(22) Filed: Apr. 14, 2022

(51) Int. Cl. H01L 23/64; H01L 23/498; H01L 23/29; H01L 23/31; H01L 23/00; H01L 21/56; H01F 27/28; H01F 27/255

(52) U.S. Cl. CPC H01L 23/645; H01L 23/49822; H01L 23/29; H01L 23/3121; H01L 24/16; H01L 21/563; H01F 27/28; H01F 27/255; H01L 2224/16227

(57) ABSTRACT

A semiconductor package includes a package substrate having a top surface including traces and bonding features. There is at least one semiconductor die including a substrate having a semiconductor surface including circuitry electrically connected to bond pads mounted on the bonding features, and at least one inductor coil mounted with a first contact and a second contact that are positioned on the bonding features beyond the semiconductor die including a portion of the inductor over the semiconductor die. There is a dielectric coating on and within the inductor coil, on the semiconductor die, on the traces, and on the bonding features. A magnetic mold compound having magnetic particles and a dielectric material encapsulates the semiconductor die, the inductor, and the dielectric coating.

### FIELD

This Disclosure relates to packaged power modules that include at least one inductor.

### BACKGROUND

A power module, such as a DC/DC switching buck converter, is conventionally implemented in one package. Such power modules combine a controller, a gate driver, power field-effect transistors (FETs), and an output inductor all in a single package. This arrangement reduces both the external component count and complexity of the power converter design.

Packaged power modules conventionally use discrete inductors that are assembled with a surface mount (SMT) process onto bonding features on the surface of a package substrate to create multichip module (MCM)/system in package (SiP) power module solutions. The inductors can make up >50% of the power module production costs. This inductor cost issue becomes even more of a factor in the case of custom inductors that have stilts as their respective contacts which enable 3D stacking of inductors on top of the die.

### SUMMARY

This Summary is provided to introduce a brief selection of disclosed concepts in a simplified form that are further described below in the Detailed Description including the drawings provided. This Summary is not intended to limit the claimed subject matter's scope.

Disclosed aspects include a power module assembly process that includes assembling inductors as part of the process utilizing lower cost inductor coils, along with a magnetic mold compound (MMC) for the molding of the package. The MMC provides both the required magnetic medium for high efficiency inductor formation and also additional benefits such as improved electromagnetic interference (EMI). The term inductor coils is used herein to differentiate from shielded inductors which lack coils.

Disclosed aspects recognize that the use of a MMC in direct contact with conventional silicon power FETs poses reliability concerns including leakage because the MMC generally has a higher electrical conductivity as compared with conventional epoxy mold compounds. To address this leakage issue, disclosed aspects after die attach include applying a conformal coating of an electrically insulating (dielectric) material on a top side of the package to electrically isolate all active surfaces including on the die and the traces on the top surface of the package substrate from the MMC. For example, the conformal coating can enable an isolation performance of 50 to 300 V/micrometer.

Disclosed aspects include a semiconductor package comprising a package substrate having a top surface including traces and bonding features. There is at least one semiconductor die comprising a substrate having a semiconductor surface including circuitry electrically connected to bond pads mounted on the bonding features, and at least one inductor coil mounted with a first contact and a second contact that are positioned on the bonding features beyond the semiconductor die including a portion of the inductor over the semiconductor die. There is a dielectric coating on and within the inductor coil, on the semiconductor die, on the traces, and on the bonding features. A magnetic mold compound comprising magnetic particles and a dielectric material encapsulates the semiconductor die, the inductor, and the dielectric coating.

### BRIEF DESCRIPTION OF THE DRAWINGS

Reference will now be made to the accompanying drawings, which are not necessarily drawn to scale, wherein:

FIGS. 1A-C are successive views of an in-process packaged power module corresponding to results following steps in an example method for forming a packaged power module including before forming the MMC applying a conformal dielectric coating on a top side of the package, according to an example aspect.

FIG. 2 is a block diagram representation of a disclosed power module that can be the basis for a disclosed packaged power module having a MMC for its molding, according to an example aspect.

### DETAILED DESCRIPTION

Example aspects are described with reference to the drawings, wherein like reference numerals are used to designate similar or equivalent elements. Illustrated ordering of acts or events should not be considered as limiting, as some acts or events may occur in different order and/or concurrently with other acts or events. Furthermore, some illustrated acts or events may not be required to implement a methodology in accordance with this Disclosure.

Also, the terms “connected to” or “connected with” (and the like) as used herein without further qualification are intended to describe either an indirect or direct electrical connection. Thus, if a first device “connects” to a second device, that connection can be through a direct electrical connection where there are only parasitics in the pathway, or through an indirect electrical connection via intervening items including other devices and connections. For indirect connecting, the intervening item generally does not modify the information of a signal but may adjust its current level, voltage level, and/or power level.

Disclosed assembly processing includes applying a dielectric coating on the top side of an in-process packaged power module after the die and inductor assembly to electrically insulate all surfaces, followed by MMC molding. The dielectric coating enables use of a reduced cost MMC (as used in discrete inductors) and to obtain a wide Vin operating range (5V-100V) for the power module.

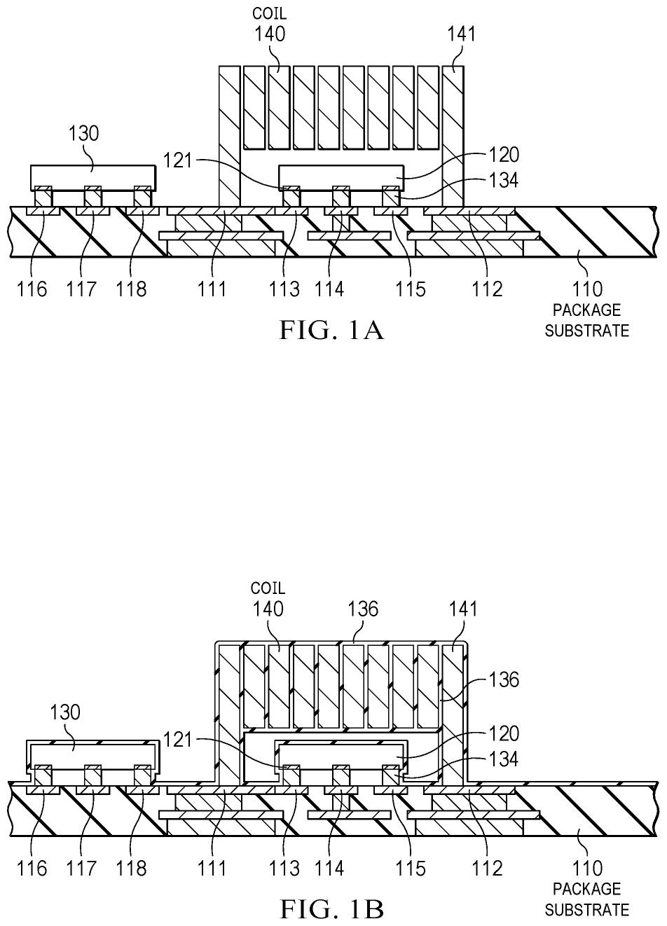

FIG. 1A is a cross-sectional depiction of an in-process power module package after surface mounting, generally using a pick and place process, of at least one semiconductor device shown as die 120 along with an optional second die shown as 130. Bond pads for the respective die are both shown as 121. The configuration can be with both die (or multiple die) underneath or besides the inductor coil 140. The power module generally includes two power FETs (high side and low side), and at least a controller and a gate driver IC. The power modules can come in various configurations, where the high side and low side power FET are generally on the same IC especially when implemented as a lateral MOSFET, and where the gate driver and the controller may be on the same IC or each on a different IC. The controller may or may not be part of the power module.

The power module also includes an inductor coil 140 mounted with stilts 141 for the respective contacts which enable the die 120 to be underneath the inductor coil that make electrical contact to contact pads 111 and 112 on a top surface of a package substrate 110 shown by example as a routable leadframe (RLF). There are also contact pads 113, 114 and 115 that the die 120 is mounted on and contact pads 116, 117 and 118 that the second die 130 is mounted on, both being flipchip mounted using a solder connection 134 as an example. Although not shown, the contact pads 116, 117 and 118 generally have a connection to a bottom side of the package substrate 110 similar to the other contact pads. Contact pads 111 and 113 are shown shorted together. The package substrate 110 can also be a leadframe or a laminate substrate.

The inductor coil can comprise a single inductor or a transformer comprising two or more inductor coils, wherein in operation one of which is powered by AC, inducing an AC voltage across the second inductor coil. The package substrate 110 can comprise a leadframe which can comprise a conventional leadframe such as a small outline integrated circuit (SOIC), thin small outline package (TSOP), heatsink small outline package (HSOP) leadframe, quad flat no leads (QFN), or a multilayer substrate such as a multilayer routable leadframe (MRLF) substrate including a first and at least a second RLF layers, for a Molded Interconnect Substrate (MIS).

FIG. 1B shows the in-process power module package after a low temperature single side (of the package substrate) conformal dielectric coating 136 of that is within the gaps in the inductor coil 140, and electrically isolates from one another the inductor coil 140, the respective die 120 and 130, and the traces on the top surface of the package substrate 110. The thickness of the dielectric coating 136 can be 0.3 to 10 μm. The disadvantage of making the thickness of the dielectric coating 136 below 0.3 um is the possible lack of sufficient voltage breakdown strength, and the disadvantage of a thickness above 10 um is significantly reduced productivity of the dielectric coating tool. Example dielectric materials for the dielectric coating 136 include boron nitride (BN), SiO₂, SiN, polyimides, silicone or parylene.

FIG. 1C shows the power module as a power module package 180 after molding to form a MMC material 145, such as using compression molding. The MMC material 145 is electrically isolated by the conformal coating 136 from active surfaces including the inductor coil 140, active surfaces on the respective die 120 and 130, and traces on the top surface of the package substrate 110. This enables the power module package 180 to provide a wide Vin range, such as 5 V to 200 V. The MMC material 145 can have a magnetic permeability from 15 to 25. The thickness of the power module package can be 1.2 mm to 2 mm.

Mounting of the die in the case of power FET(s) is generally by flipchip since that arrangement offers the best efficiency with lowest parasitics and lowest drain to source on resistance (RDSon). Wirebonding can also be used. As described above one arrangement is where the power FET, driver and controller are all integrated on a single die or collectively provided by two die, where the driver and FET are on single die and the controller is a separate die. Wirebond or flipchip may be used to mount the driver and/or the controller.

The forming of the MMC 145 can comprise compression molding using a magnetic mold compound powder comprising a plurality of magnetic particles generally spanning a range of sizes that are encapsulated by a dielectric material using hot pressing and heat. The magnetic particles can comprise iron oxide, permalloy or an amorphous alloy. The dielectric material can provide a coating for the magnetic particles.

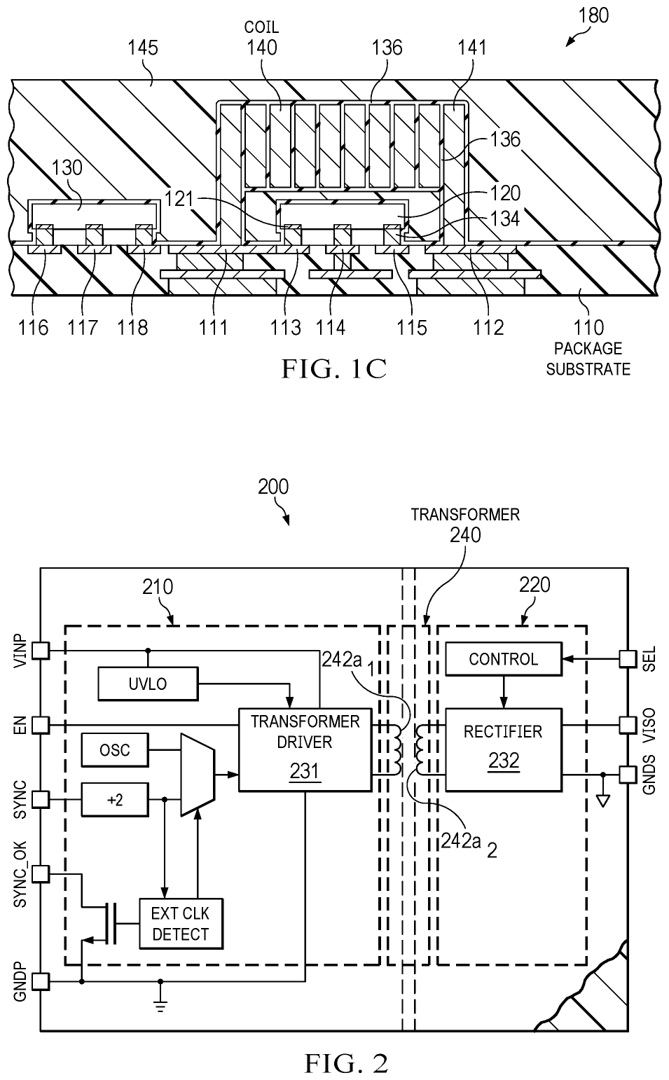

The inductor coil can comprise a transformer which generally has four contacts. The power module shown in FIG. 2 includes at least one transformer 240 which shows a functional block diagram for an example isolated DC-DC converter package 200. The isolated DC-DC converter package 200 comprises a leadframe including supports for a transformer 240 including at least a first and a second inductor coil 242a1 and 242a2, and first and second die pads with its respective pins representing the leadframe being shown.

The isolated DC-DC converter package 200 comprises a primary side including a first semiconductor die 210 that includes a transformer driver 231 and a secondary side including a second semiconductor die 220 including a rectifier 232. The transformer 240 is positioned in series to provide high-voltage isolation between the first semiconductor die 210 and the second semiconductor die 220.

Advantages of disclosed aspects include enabling the use of lower cost commercially available MMC (used in discrete inductors) to be used in power module assembly to enable better power efficiency, smaller size, lower cost, and relatively wide Vin solutions.

Although not shown, multiple ones of the packaged power modules can be processed together while in a sheet (or panel) and singulated to separate individual packaged power module units using, for example, using mechanical sawing.

### EXAMPLES

Disclosed aspects are further illustrated by the following specific Examples, which should not be construed as limiting the scope or content of this Disclosure in any way.

Disclosed aspects can be integrated into a variety of assembly flows to form a variety of different power packages and related products. A variety of package substrates may be used. The IC die may include various elements therein and/or layers thereon, including barrier layers, dielectric layers, device structures, active elements and passive elements including source regions, drain regions, bit lines, bases, emitters, collectors, conductive lines, conductive vias, etc. Moreover, the IC die can be formed from a variety of processes including bipolar, insulated-gate bipolar transistor (IGBT), CMOS, BiCMOS and MEMS.

Those skilled in the art to which this Disclosure relates will appreciate that many variations of disclosed aspects are possible within the scope of the claimed invention, and further additions, deletions, substitutions and modifications may be made to the above-described aspects without departing from the scope of this Disclosure.

1. A semiconductor package, comprising:
a package substrate having a top surface including traces and bonding features;
at least one semiconductor die comprising a substrate having a semiconductor surface including circuitry electrically coupled to bond pads mounted on the bonding features, and
at least one inductor coil mounted with a first contact and a second contact that are positioned on the bonding features beyond the semiconductor die including a portion of the inductor coil over the semiconductor die;
a dielectric coating on and within the inductor coil, on the semiconductor die, on the traces, and on the bonding features, and
a magnetic mold compound comprising magnetic particles and a dielectric material that encapsulates the semiconductor die, the inductor, and the dielectric coating.

2. The semiconductor package of claim 1, wherein the package substrate comprises a routable leadframe (RLF).

3. The semiconductor package of claim 1, wherein the magnetic particles are encapsulated by the dielectric material.

4. The semiconductor package of claim 1, wherein the magnetic mold compound has a magnetic permeability from 15 to 25.

5. The semiconductor package of claim 1, wherein the dielectric coating comprises silicon nitride, boron nitride (BN), silica, silicone or parylene.

6. The semiconductor package of claim 1, wherein the semiconductor package comprises a power module, and wherein the semiconductor die comprises both a first field effect transistor (FET), and a second FET.

7. The semiconductor package of claim 6, wherein the semiconductor die is flipchip mounted on the bonding features, and wherein the semiconductor package further comprises a gate driver.

8. The semiconductor package of claim 1, wherein the inductor coil comprises a transformer.

9. The semiconductor package of claim 1, wherein a thickness of the dielectric coating is 0.3 to 10 μm.

10. A method of forming a semiconductor package, comprising:
mounting at least one semiconductor die comprising a substrate having a semiconductor surface including circuitry electrically connected to bond pads on bonding features of a package substrate having a top surface further including traces, and an inductor coil mounted with a first contact and a second contact that are positioned on the bonding features beyond the semiconductor die including a portion of the inductor coil over the semiconductor die;
forming a dielectric coating on the inductor coil, on the semiconductor die, on the traces, and on the bonding features, and
forming a magnetic mold compound comprising magnetic particles and a dielectric material encapsulating the semiconductor die and the dielectric coating.

11. The method of claim 10, wherein the magnetic particles are encapsulated by the dielectric material.

12. The method of claim 10, wherein the package substrate comprises a routable leadframe (RLF).

13. The method of claim 10, wherein the magnetic mold compound has a magnetic permeability from 15 to 25.

14. The method of claim 10, wherein the dielectric coating comprises silicon nitride, boron nitride (BN), silica, silicone or parylene.

15. The method of claim 10, wherein the semiconductor package comprises a power module, and wherein the semiconductor die comprises both a first field effect transistor (FET), and a second FET.

16. The method of claim 10, wherein the mounting comprises flipchip mounting.

17. The method of claim 10, wherein a thickness of the dielectric coating is 0.3 to 10 μm.

18. The method of claim 10, wherein the inductor coil comprises a transformer.

19. The method of claim 10, wherein the forming of the magnetic mold compound comprises compression molding.

20. The method of claim 10, wherein the bond pads include solder thereon.
